(19) United States
(12) Patent Application Publication
(10) Pub. No.: US 2023/0317621 A1
(43) Pub. Date: Oct. 5, 2023

(54) GLASS SUBSTRATE PACKAGE WITH HYBRID BONDED DIE

(71) Applicant: Intel Corporation, Santa Clara, CA (US)

(72) Inventors: Bernd WAIDHAS, Pettendorf (DE); David O'SULLIVAN, Munich (DE); Georg SEIDEMANN, Landshut (DE)

(21) Appl. No.: 17/707,708

(22) Filed: Mar. 29, 2022

(51) Int. Cl. H01L 23/538; H01L 23/00; H01L 23/15; H01L 25/065; H01L 23/498; H01L 21/48

(52) U.S. Cl. CPC H01L 23/5384; H01L 24/08; H01L 23/5383; H01L 23/15; H01L 25/0655; H01L 24/05; H01L 24/80; H01L 23/49811; H01L 21/486; H01L 2224/08225; H01L 2224/05647; H01L 2224/80447; H01L 2224/80895

(57) ABSTRACT

Embodiments herein relate to systems, apparatuses, techniques, or processes directed to semiconductor packages that include a glass interposer that includes electrically conductive through glass vias that extend through the interposer. One or more dies may be hybrid bonded to a first side of the glass interposer. In embodiments, the second side of the glass interposer may include a redistribution layer that is electrically coupled with the one or more dies through the through glass vias. Other embodiments may be described and/or claimed.

### FIELD

Embodiments of the present disclosure generally relate to the field of package assemblies, and in particular package assemblies that include magnetic cores.

### BACKGROUND

Continued reduction in end product size of mobile electronic devices such as smart phones and ultrabooks is a driving force for the development of reduced size system in package components.

### BRIEF DESCRIPTION OF THE DRAWINGS

FIG. 1 illustrates various cross section side views of a legacy package that includes an interposer with solder connections to dies and solder connections to a substrate.

FIG. 2 illustrates a cross section side view and a top-down view of a package that includes a glass substrate hybrid bonded with dies that includes a redistribution layer (RDL) that has a solder connection to a substrate, in accordance with various embodiments.

FIG. 3 illustrates a detailed cross section side view of a portion of a package that includes a glass substrate hybrid bonded with dies that includes a RDL with solder connections, in accordance with various embodiments.

FIG. 4 illustrates a detailed cross section side view of a portion of a package that includes a glass substrate, with a first RDL on a top of the glass substrate and dies hybrid bonded with the first RDL, and a second RDL on the bottom of the glass substrate with solder connections, in accordance with various embodiments.

FIG. 5 illustrates a cross section side view of a multiple die stack with hybrid bonded dies, in accordance with various embodiments.

FIGS. 6A-6F illustrates stages in a manufacturing process for creating a package with a glass substrate, an RDL on the substrate, and dies hybrid bonded to the RDL, in accordance with various embodiments.

FIG. 7 illustrates multiple examples of laser-assisted etching of glass interconnects processes to create through glass vias (TGV), in accordance with embodiments.

FIG. 8 illustrates an example of a process for creating a glass substrate package with a hybrid bonded die, in accordance with embodiments

FIG. 9 schematically illustrates a computing device, in accordance with embodiments.

### DETAILED DESCRIPTION

Embodiments of the present disclosure may generally relate to systems, apparatuses, techniques, and/or processes directed to semiconductor packages that include a glass substrate, which may also be referred to as a glass interposer substrate. The glass substrate includes electrically conductive TGV that extend from a first side of the glass substrate to a second side of the glass substrate opposite the first side. One or more dies may be hybrid bonded to a first side of the glass substrate. In embodiments, the hybrid bonding may be a direct copper to copper hybrid bonding. In various embodiments hybrid or direct bonding may refer to the direct molecular bonding of copper interconnections disposed in two surfaces that are brought in face-to-face contact during a hybrid bonding process. In embodiments, the second side of the glass substrate may include an RDL layer that is electrically coupled with the one or more electrically conductive TGVs. In embodiments, there may be another RDL layer between the glass substrate and the one or more dies, where the one or more dies are hybrid bonded to the RDL layer.

Legacy integration semiconductor packages frequently include an organic or silicon interposer that includes solder connections on both sides of the interposer. A top set of solder connections to connect with dies on one side of the interposer. These dies may be chiplets that are coupled to the side of the interposer with solder bumps or micro bumps, which may be referred to as a first level interconnect. At the other side of the interposer, a bottom set of solder connections include a ball grid array (BGA) connection to substrate. These connections may be referred to as C4 bumps.

The solder bumps, or solder connections, on either side of the legacy interposer contribute to a large portion of connection resistance, and increase the voltage drop for either a signal routing path or for a power supply path between the die and the BGA substrate.

In embodiments described herein, the second solder interconnect is replaced by hybrid bonding dies to the interposer substrate. In embodiments, the interposer substrate is a glass substrate that is coupled with a printed circuit board (PCB) using a BGA solder interface. As a result, removing the second solder interconnect will greatly reduce the voltage drop of the package between the die and the PCB.

In embodiments, panel level production may be possible for these packages, versus implementations that use 2.5D silicon wafers that are limited to 300 mm in diameter. In addition, during manufacturing stages, the glass interposer may be part of a permanent carrier that can remain in the package. As a result, because there are no carrier release layers or processes as exist with legacy organic substrates, in embodiments interposer warpage may be reduced. In addition, as discussed further below, extreme thinning of the dies hybrid bonded to the glass interposer is possible after hybrid bonding, reducing thermal resistance to a heat spreader that may be placed on top of the thinned dies. The thinned dies may also enable backside power interconnects to the top of the dies. In addition, high-bandwidth interconnect (HBI) interconnects are possible by, for example but not limited to, micro bump soldering.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

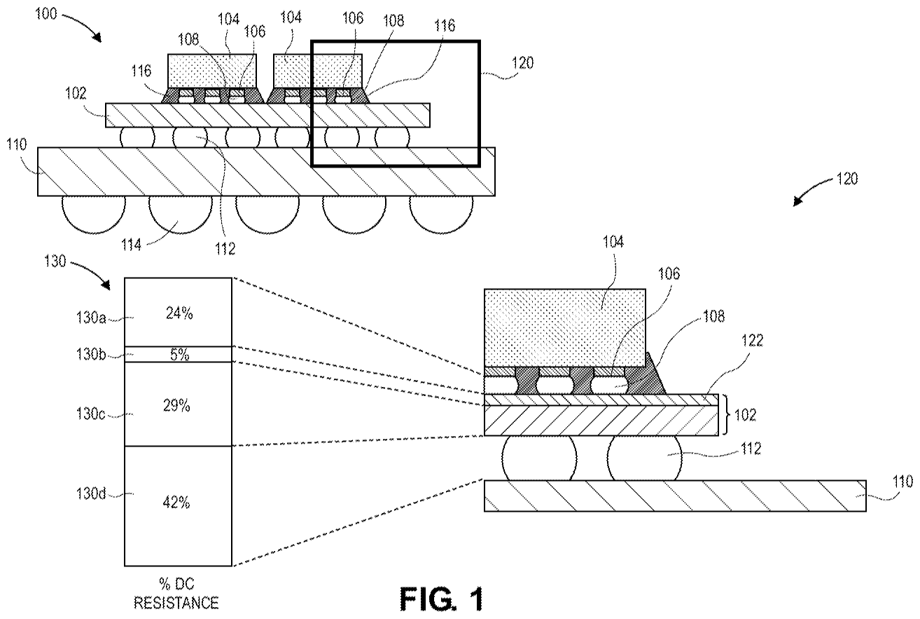

FIG. 1 illustrates various cross section side views of a legacy package that includes an interposer with solder connections to dies and solder connections to a substrate. Legacy package 100 shows a cross section side view that includes an interposer 102. A first side of the interposer is coupled with dies 104 that have metal pads 106 at the bottom of the dies 104. The metal pads 106 are electrically and physically coupled with the interposer 102 using solder balls 108.

At a second side of the interposer 102, a substrate 110, which may be a PCB substrate, is electrically and physically coupled with the interposer 102 using solder balls 112. The other side of the substrate 110 may include solder balls 114 for connections to other components (not shown), for example a PCB. In implementations, an underfill material 116, such as a mold compound, may be placed between the dies 104 and the top of the interposer 102.

Legacy package 120, which is a blowup of area 120 of legacy package 100, together with chart 130 shows a breakdown of the percentages of direct-current resistance (DCR) that are experienced between the dies 104, in particular the metal pads 106 at the bottom of the dies 104, and the substrate 110. Legacy package 120 also includes a micro bump pad layer 122, which is part of the interposer 102, and provides pads onto which solder balls 108 attach to the interposer 102.

With respect to DCR percentages, area 130a shows 24% of the DCR comes from the solder bumps 108 that couple the die 104 to the micro bump pad layer 122. Area 130b shows 5% of the DCR comes from the micro bump pad layer 122. Area 130c shows 29% of the DCR comes from the interposer body 102. Finally, area 130d shows 42% of the DCR comes from solder bumps 112 at the bottom of the interposer 102 that couple with the substrate 110. In embodiments described below, approximately 24% of the DCR, represented by area 130a, may be eliminated by removing solder balls 108 and instead using a hybrid bonding technique to directly couple the metal pads 106 to metal pads within micro bump pad layer 122.

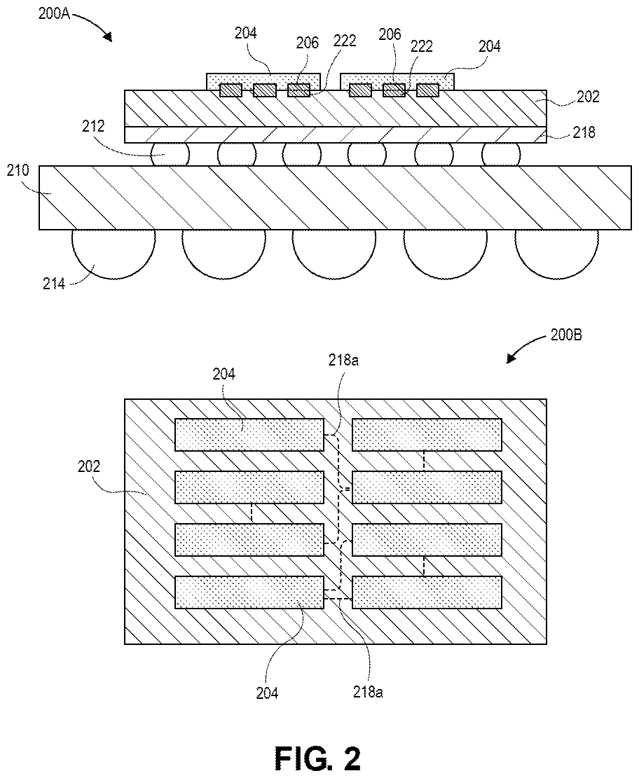

FIG. 2 illustrates a cross section side view and a top-down view of a package that includes a glass substrate hybrid bonded with dies that includes a RDL that has a solder connection to a substrate, in accordance with various embodiments. Package 200A shows a cross section side view of an interposer 202, which may be a glass substrate. Dies 204, that include metal pads 206, may be hybrid bonded to metal pads 222 at a side of the interposer 202. In embodiments, the interposer 202 may be similar to interposer 102, dies 204 may be similar to dies 104, metal pads 206 may be similar to metal pads 106, and metal pads 222 may be similar to micro bump pad layer 122 of FIG. 1.

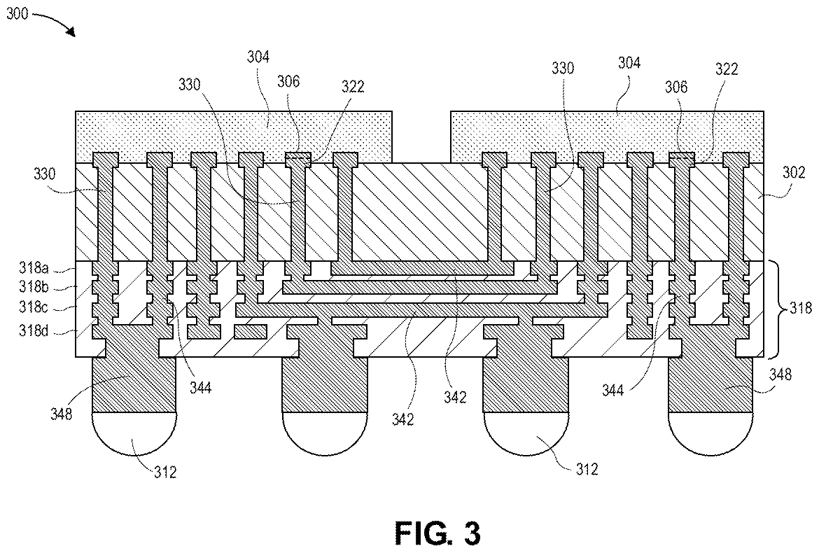

An RDL 218 may be coupled to a bottom of the glass interposer 202. The RDL 218 may electrically and physically couple with the substrate 210 using one or more solder balls 212. In embodiments, connections other than solder balls 212, for example but not limited to copper pillars, may be used. The RDL 218 may be used to route power or signals between the dies 204, and/or between the dies 204 and the substrate 210, that include solder balls 214 that may be similar to solder balls 114 of FIG. 1. The RDL 218 is discussed in greater detail with respect to FIG. 3 below.

Package 200B shows a top-down view of package 200A, with dies 204 on the glass interposer 202. Note example traces 218a within the RDL 218 that may electrically couple the various dies 204. In embodiments, example traces 218a may be used to route power or to route a signal.

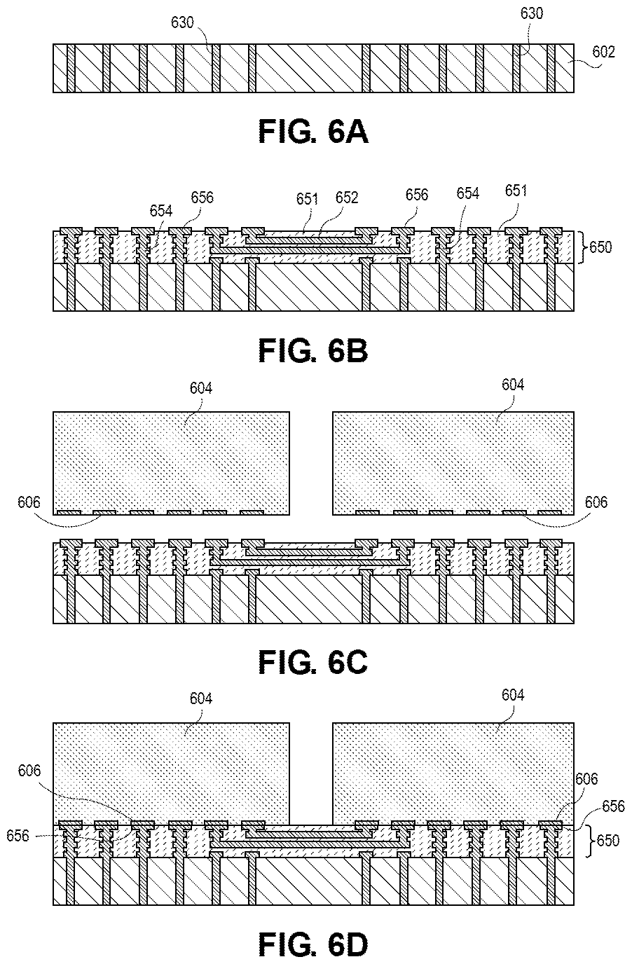

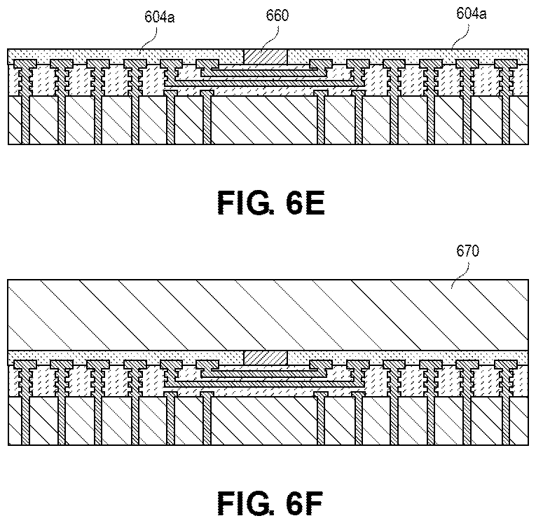

FIG. 3 illustrates a detailed cross section side view of a portion of a package that includes a glass substrate hybrid bonded with dies that includes a RDL with solder connections, in accordance with various embodiments. Package 300, which may be similar to package 200A of FIG. 2, includes a glass interposer 302 that includes metal pads 322, which may be similar to metal pads 222 of FIG. 2. Note that in embodiments, recesses within a surface of the glass interposer 302 into which metal pads 322 may be inserted may be created using techniques described below with respect to FIG. 6.

Dies 304, which may be similar to dies 204 of FIG. 2, may electrically and physically couple with the glass interposer 302 via hybrid bonding. In embodiments, dies 304 include metal pads 306, which may include copper, are bonded to the metal pads 322 during the hybrid bonding process. In embodiments, a dielectric material (not shown) may surround the metal pads 306 on the dies 304 to facilitate hybrid bonding. In some embodiments, during a hybrid bonding process dielectric material (e.g., silicon dioxide, or other oxide materials) surrounding pads 306 may directly bond with dielectric material (e.g., silicon dioxide, or other oxide materials) surrounding pads 322 before pads 306 directly bond with pads 322. The glass interposer 302 may include multiple TGV 330 that extend from a first side to a second side opposite the first side of the glass interposer 302. In embodiments, the multiple TGV 330 may be formed by using processes involving laser-assisted etching of glass described below. In embodiments, some of the TGV 330 may be filled with an electrically conductive material, which may include copper. In embodiments, at least some of the TGV 330 may be directly electrically coupled with metal pads 322 at the top of the glass interposer 302.

An RDL layer 318, which may be similar to RDL 218 of FIG. 2, is coupled to a side of the glass interposer 302. In embodiments, the RDL 318 may include a plurality of layers 318a-318d that include various electrical routings 342, and may include vias 344 that electrically couple at least some of the plurality of layers 318a-318d with each other. In embodiments, some of the electrical routings 342, and some of the vias 344, may electrically couple with at least some of the multiple TGV 330 through the glass interposer 302. In embodiments, electrical routings 342 and vias 344 may be used to route signals and/or power between the dies 304.

In embodiments, the electrical routings 342, and vias 344, may electrically couple with one or more copper pillars 348 at the bottom of the RDL 318. In embodiments, the one or more copper pillars 348 may include solder 312 to facilitate electrical and/or physical coupling with another component (not shown), such as substrate 210 of FIG. 2. In embodiments, electrical routings 342 and vias 344 may be used to route signals and/or power between the dies 304 and a substrate such as substrate 210 of FIG. 2. In embodiments, the substrate 210 may be a PCB, or another integration package.

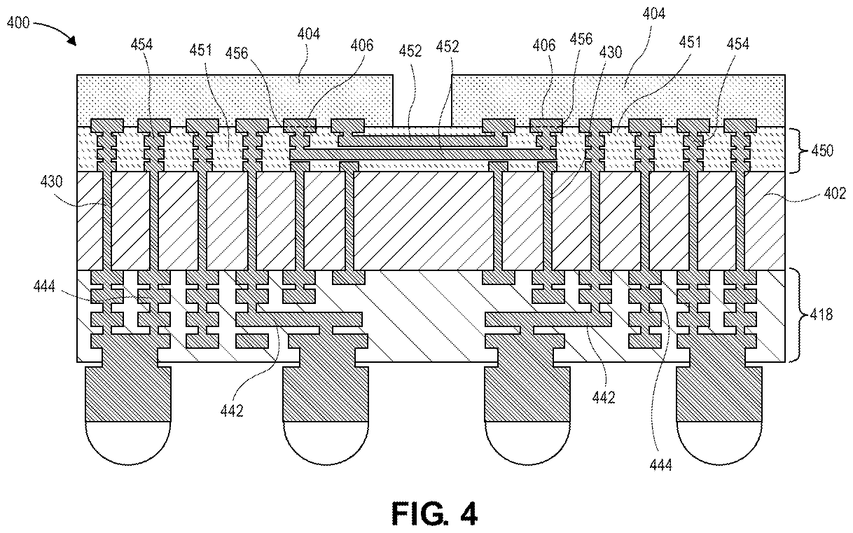

FIG. 4 illustrates a detailed cross section side view of a portion of a package that includes a glass substrate, with a first RDL on a top of the glass substrate and dies hybrid bonded with the first RDL, and a second RDL on the bottom of the glass substrate with solder connections, in accordance with various embodiments. Package 400, which may be similar to package 300 of FIG. 3, includes a glass interposer 402 that may be similar to glass interposer 302 of FIG. 3. In embodiments, multiple TGV 430, that may be similar to TGV 330 of FIG. 3, may extend from a first side to a second side opposite the first side of the glass interposer 302, and may be filled with an electrically conductive material. The bottom of the glass interposer 302 may be a RDL layer 418, which may be similar to RDL layer 318 of FIG. 3, and include various electrical routings 442 and vias 444, which may be similar to electrical routings 342 and vias 344 of FIG. 3.

A topside routing layer 450 may be electrically and physically coupled to the top of the glass interposer 402. The topside routing layer 450 may include metal pads 456, which may include copper. Dies 404 may be hybrid bonded with the top of the topside routing layer 450, with metal pads 406 of the dies 404 hybrid bonded with the metal pads 456 of the topside routing layer 450. In embodiments, a dielectric material 451 may separate the metal pads 456 in order to facilitate hybrid bonding. In embodiments, the dielectric material 451 may include an oxide and/or organic passivations.

The topside routing layer 450 may include various electrical routings 452 and vias 454 that may be used to electrically couple at least some of the dies 404 with each other. Note that in this configuration, signal routing may occur between dies 404 using at least some of the electrical routings 452 and vias 454. Power routing may occur between the RDL layer 418 and the dies 404 using at least some of the TGV 430.

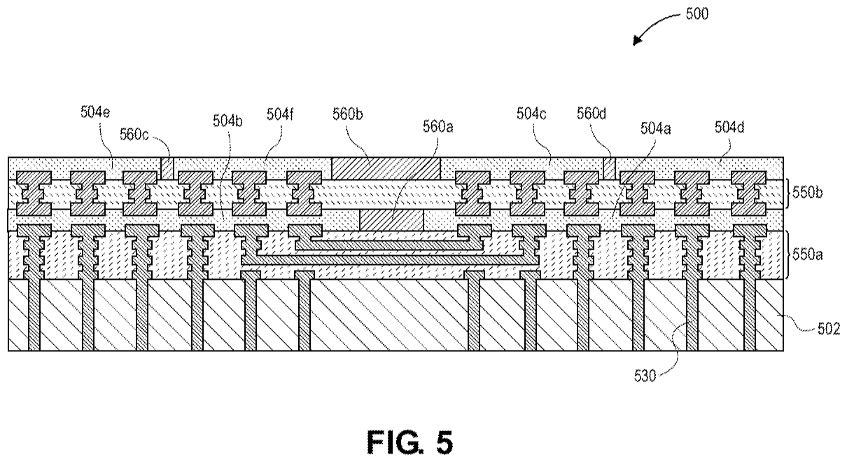

FIG. 5 illustrates a cross section side view of a multiple die stack with hybrid bonded dies, in accordance with various embodiments. Package 500, which may be similar to package 400 of FIG. 4 or package 300 of FIG. 3, includes a plurality of levels of dies that are stacked on each other. A glass interposer 502, which may be similar to glass interposer 402 of FIG. 4, may include multiple TGV 530, which may be similar to TGV 430 of FIG. 4.

A first RDL layer 550a, which may be similar to topside routing layer 450 of FIG. 4, may be on top of the class interposer 502. Using embodiments described herein, a first die 504a and a second die 504b may be hybrid bonded onto the first RDL layer 550a. A filler 560a may be placed between the first die 504a and the second die 504b, and on top of the first RDL layer 550a.

A second RDL layer 550b, which may be similar to first RDL layer 550a, may be placed on top of the first die 504a and the second die 504b. In embodiments, the second RDL layer 550b may be hybrid bonded to the first die 504a and the second die 504b

In embodiments, a third die 504c and a fourth die 504d may be hybrid bonded to the second RDL layer 550b, and may be above first die 504a. A filler 560d may be placed between the third die 504c and the fourth die 504d, and on top of the second RDL layer 550b. A fifth die 504e and a sixth die 504f may be hybrid bonded to the second RDL layer 550b, and may be above second die 504b. A filler 560c may be placed between the fifth die 504e and the sixth die 504f, and on top of the second RDL layer 550b. A filler 560b may be placed between the sixth die 504f and the third die 504c, and on top of the second RDL layer 550b.

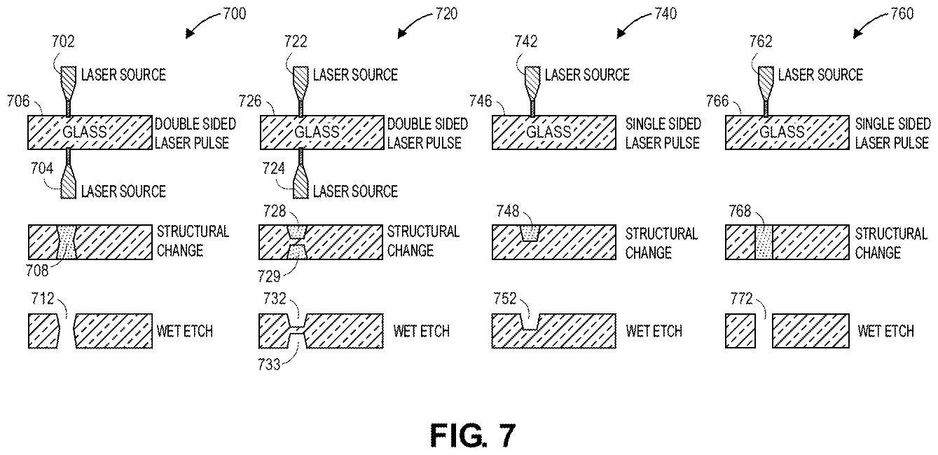

FIGS. 6A-6F illustrates stages in a manufacturing process for creating a package with a glass substrate, an RDL on the substrate, and dies hybrid bonded to the RDL, in accordance with various embodiments. FIG. 6A shows a cross section side view of a stage in the manufacturing process where a glass substrate 602 is provided. In embodiments, the glass substrate 602 may be similar to glass substrate 402 of FIG. 4, and may also be referred to as a glass interposer. One or more TGV 630, which may be similar to TGV 430 of FIG. 4, may be formed within the glass substrate 602 using the techniques described below with respect to FIG. 7. In embodiments, the TGV 630 may be filled with an electrically conductive material, such as copper. In embodiments, the TGV 630 may have a small pitch scaling, for example a sub-10 μm pitch.

FIG. 6B shows a cross section side view of a stage in the manufacturing process where an RDL 650 is formed on a side of the glass substrate 602. The RDL 650 may be similar to topside routing layer 450 of FIG. 4. In embodiments, the RDL 650 may include a plurality of sub-layers that may be formed using legacy buildup techniques. In embodiments, these techniques may include back-end-of-line (BEOL) technology processes. The RDL 650 may include various electrical routings 652 and vias 654, which may be similar to electrical routings 452 and vias 454 of FIG. 4.

In embodiments, the electrical routings 652 and vias 654 may electrically couple with at least some of the one or more TGV 630. Metal pads 656 may be on a surface of the RDL 650, may be electrically coupled with the electrical routings 652 and vias 654, and may also be used for hybrid bonding at later stages. A dielectric material 651, which may be similar to dielectric material 451 of FIG. 4, may separate the metal pads 656.

FIG. 6C shows a cross section side view of a stage in the manufacturing process where dies 604 are provided. In embodiments, the dies 604, which may be similar to dies 404 of FIG. 4, may include metal pads 606, which may be similar to metal pads 406 of FIG. 4.

FIG. 6D shows a cross section side view of a stage in the manufacturing process where dies 604 are hybrid bonded to RDL 650. In embodiments, the metal pads 606 of dies 604 will be bonded with the metal pads 656 of the RDL 650 during the hybrid bonding process. The hybrid bonding process may involve a series of stages. For example, a first stage of the hybrid bonding process may involve bringing the dies 604 and the RDL 650 together physically, where the die metal pads 606 and the metal pads 656 are aligned with each other. This may be done at a lower temperature, for example at an ambient room temperature. A second stage of the hybrid bonding process may involve applying heat so that the die metal pads 606 and the metal pads 656 are brought into physical contact with each other. A third stage of a hybrid bonding process may involve applying further heat to compress the die metal pads 606 and the metal pads 656, creating a bonding between them that has very low electrical resistance.

FIG. 6E shows a cross section side view of a stage in the manufacturing process where dies 604a, which may be similar to dies 604 of FIG. 6D, are thinned, and a filler 660 may be placed between the dies 604a. In embodiments, the filler may include, but not be limited to, a mold compound or an oxide for planarization for subsequent metallization layers (not shown), or a metal for thermal coupling of the dies 604.

FIG. 6F shows a cross section side view of a stage in the manufacturing process where a heat spreader 670 is placed over the thinned dies 604a and the filler 660. In embodiments, the heat spreader 670 may include materials such as but not limited to metal or metal alloys, for example copper. In embodiments, a thermal interface material (not shown) may be placed between the heat spreader 670 and a surface of the thinned dies 604a and filler 660.

FIG. 7 illustrates multiple examples of laser-assisted etching of glass interconnects processes that may be used to create TGV, in accordance with embodiments. FIG. 7 illustrates multiple examples of laser-assisted etching of glass interconnects processes (which may be referred to as “LEGIT” herein), in accordance with embodiments. One use of the LEGIT technique is to provide an alternative substrate core material to the legacy copper clad laminate (CCL) core used in semiconductor packages used to implement products such as servers, graphics, clients, 5G, and the like. By using laser-assisted etching, crack free, high density via drills, hollow shapes may be formed into a glass substrate. In embodiments, different process parameters may be adjusted to achieve drills of various shapes and depths, thus opening the door for innovative devices, architectures, processes, and designs in glass. Embodiments, such as the bridge discussed herein, may also take advantage of these techniques.

Diagram 700 shows a high level process flow for a through via and blind via (or trench) in a microelectronic package substrate (e.g. glass) using LEGIT to create a through via or a blind via. A resulting volume/shape of glass with laser-induced morphology change that can then be selectively etched to create a trench, a through hole or a void that can be filled with conductive material. A through via 712 is created by laser pulses from two laser sources 702, 704 on opposite sides of a glass wafer 706. As used herein, a through drill and a through via refers to when the drill or the via starts on one side of the glass/substrate and ends on the other side. A blind drill and a blind via refers to when the drill or the via starts on the surface of the substrate and stops half way inside the substrate. In embodiments, the laser pulses from the two laser sources 702, 704 are applied perpendicularly to the glass wafer 706 to induce a morphological change 708, which may also be referred to as a structural change, in the glass that encounters the laser pulses. This morphological change 708 includes changes in the molecular structure of the glass to make it easier to etch out (remove a portion of the glass). In embodiments, a wet etch process may be used.

Diagram 720 shows a high level process flow for a double blind shape. A double blind shape 732, 733 may be created by laser pulses from two laser sources 722, 724, which may be similar to laser sources 702, 704, that are on opposite sides of the glass wafer 726, which may be similar to glass wafer 706. In this example, adjustments may be made in the laser pulse energy and/or the laser pulse exposure time from the two laser sources 722, 724. As a result, morphological changes 728, 729 in the glass 726 may result, with these changes making it easier to etch out portions of the glass. In embodiments, a wet etch process may be used.

Diagram 740 shows a high level process flow for a single-blind shape, which may also be referred to as a trench. In this example, a single laser source 742 delivers a laser pulse to the glass wafer 746 to create a morphological change 748 in the glass 746. As described above, these morphological changes make it easier to etch out a portion of the glass 752. In embodiments, a wet etch process may be used.

Diagram 760 shows a high level process flow for a through via shape. In this example, a single laser source 762 applies a laser pulse to the glass 766 to create a morphological change 768 in the glass 766, with the change making it easier to etch out a portion of the glass 772. As shown here, the laser pulse energy and/or laser pulse exposure time from the laser source 762 has been adjusted to create an etched out portion 772 that extends entirely through the glass 766.

With respect to FIG. 7, although embodiments show laser sources 702, 704, 722, 724, 742, 762 as perpendicular to a surface of the glass 706, 726, 746, 766, in embodiments, the laser sources may be positioned at an angle to the surface of the glass, with pulse energy and/or pulse exposure time variations in order to cause a diagonal via or a trench, or to shape the via, such as 712, 772, for example to make it cylindrical, tapered, or include some other feature. In addition, varying the glass type may also cause different features within a via or a trench as the etching of glass is strongly dependent on the chemical composition of the glass.

In embodiments using the process described with respect to FIG. 7, through hole vias 712, 772 may be created that are less than 10 μm in diameter, and may have an aspect ratio of 40:1 to 50:1. As a result, a far higher density of vias may be placed within the glass and be placed closer to each other at a fine pitch. In embodiments, this pitch may be 50 μm or less. After creating the vias or trenches, a metallization process may be applied in order to create a conductive pathway through the vias or trenches, for example a plated through hole (PTH). Using these techniques, finer pitch vias will result in better signaling, allowing more I/O signals to be put through the glass wafer and to other coupled components such as a substrate.

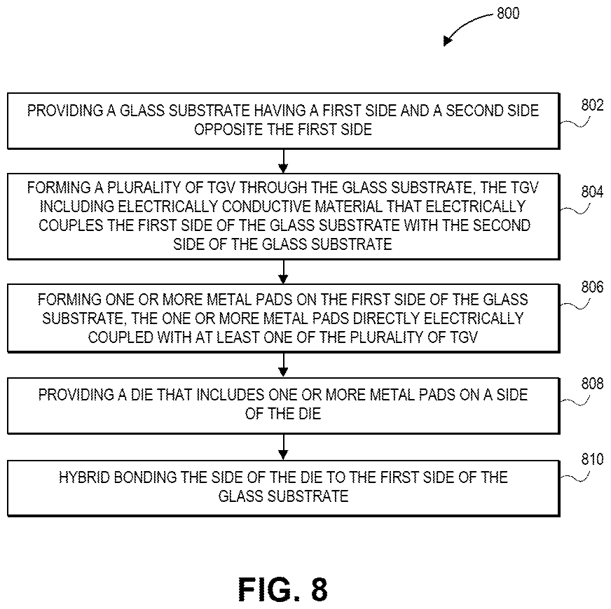

FIG. 8 illustrates an example of a process for creating a glass substrate package with a hybrid bonded die, in accordance with embodiments. Process 800 may be performed by one or more elements, techniques, or systems that may be described herein, and in particular with respect to FIGS. 1-7.

At block 802, the process may include providing a glass substrate having a first side and a second side opposite the first side. In embodiments, the glass substrate may be similar to glass substrate 202 of FIG. 2, or glass substrate 302 of FIG. 3.

At block 804, the process may further include forming a plurality of TGV through the glass substrate, the TGV including electrically conductive material that electrically couples the first side of the glass substrate with the second side of the glass substrate. In embodiments, the plurality of TGV may be similar to TGV 330 of FIG. 3.

At block 806, the process may further include forming one or more metal pads on the first side of the glass substrate, the one or more metal pads directly electrically coupled with at least one of the plurality of TGV. In embodiments, the one or more metal pads may be similar to metal pads 222 of FIG. 2, or metal pads 322 of FIG. 3.

At block 808, the process may further include providing a die that includes one or more metal pads on a side of the die. In embodiments, the die may be similar to dies 204 of FIG. 2, or 304 of FIG. 3.

At block 810, the process may further include hybrid bonding the side of the die to the first side of the glass substrate. In embodiments, the hybrid bonding may be similar to the hybrid bonding of the dies 304 to the substrate 302 as shown in FIG. 3.

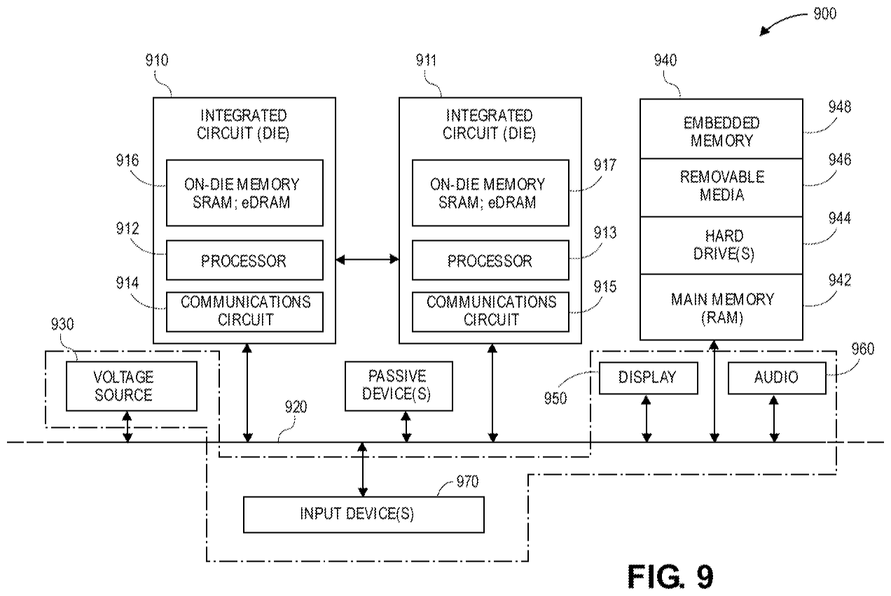

FIG. 9 is a schematic of a computer system 900, in accordance with an embodiment of the present invention. The computer system 900 (also referred to as the electronic system 900) as depicted can embody a glass substrate package with a hybrid bonded die, according to any of the several disclosed embodiments and their equivalents as set forth in this disclosure. The computer system 900 may be a mobile device such as a netbook computer. The computer system 900 may be a mobile device such as a wireless smart phone. The computer system 900 may be a desktop computer. The computer system 900 may be a hand-held reader. The computer system 900 may be a server system. The computer system 900 may be a supercomputer or high-performance computing system.

In an embodiment, the electronic system 900 is a computer system that includes a system bus 920 to electrically couple the various components of the electronic system 900. The system bus 920 is a single bus or any combination of busses according to various embodiments. The electronic system 900 includes a voltage source 930 that provides power to the integrated circuit 910. In some embodiments, the voltage source 930 supplies current to the integrated circuit 910 through the system bus 920.

The integrated circuit 910 is electrically coupled to the system bus 920 and includes any circuit, or combination of circuits according to an embodiment. In an embodiment, the integrated circuit 910 includes a processor 912 that can be of any type. As used herein, the processor 912 may mean any type of circuit such as, but not limited to, a microprocessor, a microcontroller, a graphics processor, a digital signal processor, or another processor. In an embodiment, the processor 912 includes, or is coupled with, a glass substrate package with a hybrid bonded die, as disclosed herein. In an embodiment, SRAM embodiments are found in memory caches of the processor. Other types of circuits that can be included in the integrated circuit 910 are a custom circuit or an application-specific integrated circuit (ASIC), such as a communications circuit 914 for use in wireless devices such as cellular telephones, smart phones, pagers, portable computers, two-way radios, and similar electronic systems, or a communications circuit for servers. In an embodiment, the integrated circuit 910 includes on-die memory 916 such as static random-access memory (SRAM). In an embodiment, the integrated circuit 910 includes embedded on-die memory 916 such as embedded dynamic random-access memory (eDRAM).

In an embodiment, the integrated circuit 910 is complemented with a subsequent integrated circuit 911. Useful embodiments include a dual processor 913 and a dual communications circuit 915 and dual on-die memory 917 such as SRAM. In an embodiment, the dual integrated circuit 910 includes embedded on-die memory 917 such as eDRAM.

In an embodiment, the electronic system 900 also includes an external memory 940 that in turn may include one or more memory elements suitable to the particular application, such as a main memory 942 in the form of RAM, one or more hard drives 944, and/or one or more drives that handle removable media 946, such as diskettes, compact disks (CDs), digital variable disks (DVDs), flash memory drives, and other removable media known in the art. The external memory 940 may also be embedded memory 948 such as the first die in a die stack, according to an embodiment.

In an embodiment, the electronic system 900 also includes a display device 950, an audio output 960. In an embodiment, the electronic system 900 includes an input device such as a controller 970 that may be a keyboard, mouse, trackball, game controller, microphone, voice-recognition device, or any other input device that inputs information into the electronic system 900. In an embodiment, an input device 970 is a camera. In an embodiment, an input device 970 is a digital sound recorder. In an embodiment, an input device 970 is a camera and a digital sound recorder.

As shown herein, the integrated circuit 910 can be implemented in a number of different embodiments, including a package substrate having a glass substrate package with a hybrid bonded die, according to any of the several disclosed embodiments and their equivalents, an electronic system, a computer system, one or more methods of fabricating an integrated circuit, and one or more methods of fabricating an electronic assembly that includes a package substrate having a glass substrate package with a hybrid bonded die, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having a glass substrate package with a hybrid bonded die embodiments and their equivalents. A foundation substrate may be included, as represented by the dashed line of FIG. 9. Passive devices may also be included, as is also depicted in FIG. 9.

### EXAMPLES

The following paragraphs describe examples of various embodiments.

Example 1 is a package comprising: a glass substrate with a first side and a second side opposite the first side; one or more through glass vias (TGV) that include conductive material, the one or more TGV extend through the glass substrate from the first side to the second side; one or more metal pads on the first side of the glass substrate, at least one of the one or more metal pads directly electrically coupled with one of the one or more TGV; a die with a first side and a second side opposite the first side, the first side of the die including one or more metal pads; and wherein the first side of the die is hybrid bonded with the first side of the glass substrate.

Example 2 may include the package of example 1, or of any other example or embodiment described herein, further comprising a redistribution layer (RDL), wherein a side of the RDL is coupled with the second side of the glass substrate.

Example 3 may include the package of example 2, or of any other example or embodiment described herein, wherein the RDL is formed using a backend of line (BEOL) process.

Example 4 may include the package of example 2, or of any other example or embodiment described herein, wherein the RDL includes one or more electrical traces that electrically couple with at least one of the one or more TGV.

Example 5 may include the package of example 4, or of any other example or embodiment described herein, wherein the die is a plurality of dies.

Example 6 may include the package of example 5, or of any other example or embodiment described herein, wherein at least two of the plurality of dies are electrically coupled through the one or more electrical traces within the RDL.

Example 7 may include the package of example 2, or of any other example or embodiment described herein, wherein the side of the RDL is a first side; and further comprising: a second side of the RDL opposite the first side; and a plurality of electrical connectors on the second side of the RDL electrically coupled with at least one of the one or more TGV.

Example 8 may include the package of example 7, or of any other example or embodiment described herein, wherein the plurality of electrical connectors on the second side of the RDL include a selected one or more of: solder connectors, copper connectors, or hybrid bonded connectors.

Example 9 may include the package of example 1, or of any other example or embodiment described herein, wherein a thickness of the die is less than 20 μm.

Example 10 may include the package of example 1, or of any other example or embodiment described herein, wherein the one or more TGV is a plurality of TGV, and wherein a pitch of the plurality of TGV is less than 10 μm.

Example 11 may include the package of example 1, or of any other example or embodiment described herein, wherein the first side of the die includes a dielectric surrounding the one or more metal pads.

Example 12 may include the package of example 1, or of any other example or embodiment described herein, wherein the conductive material and the metal pads include copper.

Example 13 is a package comprising: a glass substrate having a first side and a second side opposite the first side; a plurality of through glass vias (TGV) that include conductive material, the plurality of TGV extend through the glass substrate from the first side to the second side; a first routing layer having a first side and a second side opposite the first side, the first side of the first routing layer coupled with the second side of the glass substrate, the first routing layer including one or more electrical traces that are electrically coupled with at least one of the plurality of TGV; wherein the second side of the first routing layer includes one or more metal pads that are electrically coupled with the one or more electrical traces of the first routing layer; and a die on the second side of the first routing layer, a side of the die including one or more metal pads, wherein the side of the die is hybrid bonded to the second side of the first routing layer.

Example 14 includes the package of example 13, or of any other example or embodiment described herein, wherein the first routing layer includes an inorganic dielectric material.

Example 15 includes a package of example 13, or of any other example or embodiment described herein, wherein the die is a plurality of dies.

Example 16 includes the package of example 15, or of any other example or embodiment described herein, wherein at least two of the plurality of dies are electrically coupled by the one or more electrical traces of the first routing layer.

Example 17 includes the package of example 13, or of any other example or embodiment described herein, further comprising: a second routing layer with a side of the second routing layer coupled with the first side of the glass substrate, wherein the second routing layer includes one or more electrical traces that are electrically coupled with at least one of the plurality of TGV.

Example 18 includes the package of example 17, or of any other example or embodiment described herein, wherein the side of the second routing layer is a first side; and further comprising: a second side of the second routing layer opposite the first side, a plurality of electrical connectors on the second side of the second routing layer electrically coupled with at least one of the plurality of TGV.

Example 19 includes the package of example 18, or of any other example or embodiment described herein, wherein at least some of the plurality of electrical traces in the first routing layer route signals, and wherein at least some of the plurality of electrical traces in the second routing layer route power.

Example 20 includes the package of example 18, or of any other example or embodiment described herein, wherein the plurality of electrical connectors on the second side of the second routing layer include a selected one or more of: solder connectors, copper connectors, or hybrid bonded connectors.

Example 21 includes the package of example 13, or of any other example or embodiment described herein, wherein a thickness of the die is less than 20 μm.

Example 22 includes a package of example 13, or of any other example or embodiment described herein, wherein a pitch of the plurality of TGV is less than 10 μm.

Example 23 is a method comprising: providing a glass substrate having a first side and a second side opposite the first side; forming a plurality of TGV through the glass substrate, the TGV including electrically conductive material that electrically couples the first side of the glass substrate with the second side of the glass substrate; forming one or more metal pads on the first side of the glass substrate, the one or more metal pads directly electrically coupled with at least one of the plurality of TGV; providing a die that includes one or more metal pads on a side of the die; and hybrid bonding the side of the die to the first side of the glass substrate.

Example 24 includes the method of example 23, or of any other example or embodiment described herein, further comprising forming a routing layer on the second side of the glass substrate, the routing layer including one or more electrical traces that electrically couple with at least one of the plurality of TGV.

Example 25 includes the method of example 24, or of any other example or embodiment described herein, wherein the die is a plurality of dies, and wherein one or more electrical traces of the routing layer electrically couple at least two of the plurality of dies.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

What is claimed is:

1. A package comprising:
a glass substrate with a first side and a second side opposite the first side;
one or more through glass vias (TGV) that include conductive material, the one or more TGV extend through the glass substrate from the first side to the second side;
one or more metal pads on the first side of the glass substrate, at least one of the one or more metal pads directly electrically coupled with one of the one or more TGV;
a die with a first side and a second side opposite the first side, the first side of the die including one or more metal pads; and
wherein at least one metal pad of the die is directly bonded with at least one of the metal pads of the glass substrate.

2. The package of claim 1, further comprising a redistribution layer (RDL), wherein a side of the RDL is coupled with the second side of the glass substrate.

3. The package of claim 2, wherein the RDL is formed using a backend of line (BEOL) process.

4. The package of claim 2, wherein the RDL includes one or more electrical traces that electrically couple with at least one of the one or more TGV.

5. The package of claim 4, wherein the die is a plurality of dies.

6. The package of claim 5, wherein at least two of the plurality of dies are electrically coupled through the one or more electrical traces within the RDL.

7. The package of claim 2, wherein the side of the RDL is a first side; and further comprising:
a second side of the RDL opposite the first side; and
a plurality of electrical connectors on the second side of the RDL electrically coupled with at least one of the one or more TGV.

8. The package of claim 7, wherein the plurality of electrical connectors on the second side of the RDL include a selected one or more of: solder connectors, copper connectors, or hybrid bonded connectors.

9. The package of claim 1, wherein a thickness of the die is less than 20 μm.

10. The package of claim 1, wherein the one or more TGV is a plurality of TGV, and wherein a pitch of the plurality of TGV is less than 10 μm.

11. The package of claim 1, wherein the first side of the die includes a dielectric surrounding the one or more metal pads.

12. The package of claim 1, wherein the conductive material and the metal pads include copper.

13. A package comprising:
a glass substrate having a first side and a second side opposite the first side;
a plurality of through glass vias (TGV) that include conductive material, the plurality of TGV extend through the glass substrate from the first side to the second side;
a first routing layer having a first side and a second side opposite the first side, the first side of the first routing layer coupled with the second side of the glass substrate, the first routing layer including one or more electrical traces that are electrically coupled with at least one of the plurality of TGV;
wherein the second side of the first routing layer includes one or more metal pads that are electrically coupled with the one or more electrical traces of the first routing layer; and
a die on the second side of the first routing layer, a side of the die including one or more metal pads, wherein at least one metal pad of the die is directly bonded to at least one of the metal pads of the first routing layer.

14. The package of claim 13, wherein the first routing layer includes an inorganic dielectric material.

15. The package of claim 13, wherein the die is a plurality of dies.

16. The package of claim 15, wherein at least two of the plurality of dies are electrically coupled by the one or more electrical traces of the first routing layer.

17. The package of claim 13, further comprising:
a second routing layer with a side of the second routing layer coupled with the first side of the glass substrate, wherein the second routing layer includes one or more electrical traces that are electrically coupled with at least one of the plurality of TGV.

18. The package of claim 17, wherein the side of the second routing layer is a first side; and further comprising:
a second side of the second routing layer opposite the first side,
a plurality of electrical connectors on the second side of the second routing layer electrically coupled with at least one of the plurality of TGV.

19. The package of claim 18, wherein at least some of the plurality of electrical traces in the first routing layer route signals, and wherein at least some of the plurality of electrical traces in the second routing layer route power.

20. The package of claim 18, wherein the plurality of electrical connectors on the second side of the second routing layer include a selected one or more of: solder connectors, copper connectors, or hybrid bonded connectors.

21. The package of claim 13, wherein a thickness of the die is less than 20 μm.

22. The package of claim 13, wherein a pitch of the plurality of TGV is less than 10 μm.

23. A method comprising:
providing a glass substrate having a first side and a second side opposite the first side;
forming a plurality of TGV through the glass substrate, the TGV including electrically conductive material that electrically couples the first side of the glass substrate with the second side of the glass substrate;
forming one or more metal pads on the first side of the glass substrate, the one or more metal pads directly electrically coupled with at least one of the plurality of TGV;
providing a die that includes one or more metal pads on a side of the die; and
directly bonding at least one of the metal pads on the side of the die to at least one of the metal pads on the first side of the glass substrate.

24. The method of claim 23, further comprising forming a routing layer on the second side of the glass substrate, the routing layer including one or more electrical traces that electrically couple with at least one of the plurality of TGV.

25. The method of claim 24, wherein the die is a plurality of dies, and wherein one or more electrical traces of the routing layer electrically couple at least two of the plurality of dies.
